(19) United States
(12) Patent Application Publication
(10) Pub. No.: US 2013/0193443 A1
(43) Pub. Date: Aug. 1, 2013

(54) SEMICONDUCTOR LIGHT EMITTING DEVICE AND METHOD FOR MANUFACTURING THE SAME

(71) Applicant: Kabushiki Kaisha Toshiba, Minato-ku (JP)

(72) Inventors: Toshihide ITO, Tokyo (JP); Hiroshi KATSUNO, Tokyo (JP); Taisuke SATO, Kanagawa-ken (JP); Shinya NUNOUE, Chiba-ken (JP)

(73) Assignee: Kabushiki Kaisha Toshiba, Minato-ku (JP)

(21) Appl. No.: 13/744,997

(22) Filed: Jan. 18, 2013

Related U.S. Application Data
(63) Continuation of application No. 13/601,800, filed on Aug. 31, 2012, now abandoned.

(30) Foreign Application Priority Data
Dec. 9, 2011 (JP) 2011-270682
Nov. 7, 2012 (JP) 2012-245820

(51) Int. Cl. H01L 33/40; H01L 33/32

(52) U.S. Cl. CPC H01L 33/405; H01L 33/32
USPC 257/76; 438/29

(57) ABSTRACT

According to one embodiment, a semiconductor light emitting device includes a semiconductor stacked unit and a silver layer. The semiconductor stacked unit includes a light emitting layer, and a semiconductor layer containing gallium provided on the light emitting layer. The silver layer contacts the semiconductor layer. A peak height belonging to a (100) plane of silver is not more than 3% of a peak height belonging to a (111) plane in an X-ray analysis. A detected intensity of a complex of gallium and nitrogen atoms at a first position is 1/100 of a maximum value in the semiconductor layer in a mass analysis. A detected intensity of gallium atoms at a second position at 40 nm distance from the first position is higher than 0.4% and lower than 3.8% of a maximum value of the detected intensity of gallium atoms in the semiconductor layer in the mass analysis.

### CROSS-REFERENCE TO RELATED APPLICATIONS

This is a Continuation-in-Part application of application Ser. No. 13/601,800, filed on Aug. 31, 2012; the entire contents of which are incorporated herein by reference.

This application is based upon and claims the benefit of priority from the prior Japanese Patent Application No. 2011-270682, filed on Dec. 9, 2011 and from the prior Japanese Patent Application No. 2012-245820, filed on Nov. 7, 2012; the entire contents of which are incorporated herein by reference.

### FIELD

Embodiments described herein relate generally to a semiconductor light emitting device and a method for manufacturing the same.

### BACKGROUND

In a semiconductor light emitting device such as an LED (Light Emitting Diode), there is a configuration of using silver (Ag) with high reflectivity as an electrode so as to increase light extraction efficiency. When the Ag electrode is thermally treated so as to cause the same to make an ohmic contact with a semiconductor layer, the reflectivity decreases in some cases, so it is difficult to simultaneously obtain low contact resistance and high reflectivity.

### BRIEF DESCRIPTION OF THE DRAWINGS

FIG. 1 is a schematic cross sectional diagram showing a semiconductor light emitting device of a first embodiment;

FIG. 2A to FIG. 2C are schematic cross sectional diagrams showing a part of the semiconductor light emitting device of the first embodiment;

FIG. 3 is a diagram of a graph showing characteristics of the semiconductor light emitting device;

FIG. 4A to FIG. 4D are diagrams of electron micrographs showing examples of the characteristics of the semiconductor light emitting device;

FIG. 5 is a diagram of a graph showing characteristics of the semiconductor light emitting device;

FIG. 6 is a diagram of a graph showing characteristics of the semiconductor light emitting device;

FIG. 7A and FIG. 7B are diagrams of electron micrographs showing the characteristics of the semiconductor light emitting device;

FIG. 8A to FIG. 8C and FIG. 9A to FIG. 9C are diagrams of X-ray diffraction profiles showing the characteristics of the semiconductor light emitting device;

FIG. 10 is a diagram of a graph showing characteristics of the semiconductor light emitting devices;

FIG. 11A to FIG. 11F are diagrams of graphs showing characteristics of the semiconductor light emitting device;

FIG. 12 is a schematic cross sectional diagram showing a configuration of another semiconductor light emitting device of the first embodiment;

FIGS. 13A to 13C, FIG. 14A, and FIG. 14B are schematic cross sectional diagrams in a processing order showing a method for manufacturing another semiconductor light emitting device of the first embodiment; and

FIG. 15 is a diagram of a flowchart showing the method for manufacturing a semiconductor light emitting device of the second embodiment.

### DETAILED DESCRIPTION

According to one embodiment, a semiconductor light emitting device includes a semiconductor stacked unit and a silver layer. The semiconductor stacked unit includes a light emitting layer and a semiconductor layer. The light emitting layer includes a nitride semiconductor. The semiconductor layer is provided on the light emitting layer. The semiconductor layer contains gallium. The silver layer is in contact with the semiconductor layer. A height of a peak belonging to a (100) plane of silver of the silver layer is not more than 3% of a height of a peak belonging to a (111) plane of silver of the silver layer in an X-ray analysis. A detected intensity of a complex of gallium atoms and nitrogen atoms at a first position is 1/100 of a maximum value of the detected intensity of the complex in the semiconductor layer in a secondary ion mass analysis. The first position is in a region including the semiconductor layer and the silver layer and along a stacking direction from the semiconductor layer toward the silver layer. A detected intensity of gallium atoms at a second position is higher than 0.4% and lower than 3.8% of a maximum value of a detected intensity of gallium atoms in the semiconductor layer in the secondary ion mass analysis. The second position is in the silver layer and a distance between the second position and the first position is 40 nm

Various embodiments will be described hereinafter with reference to the accompanying drawings.

Note that, the drawings are schematic and conceptual, thus may not necessarily have identical relationship of thickness and width of respective sections, size rate between sections and the like as those of an actual device. Further, even in cases of indicating the same section, dimensions and rates may be expressed differently depending on the drawings.

Note that, in the specification and the respective drawings, same reference sign will be given to a component identical to one that already had been explained in connection to an already-indicated drawing, and detailed explanation thereof will be omitted as needed.

### Embodiment

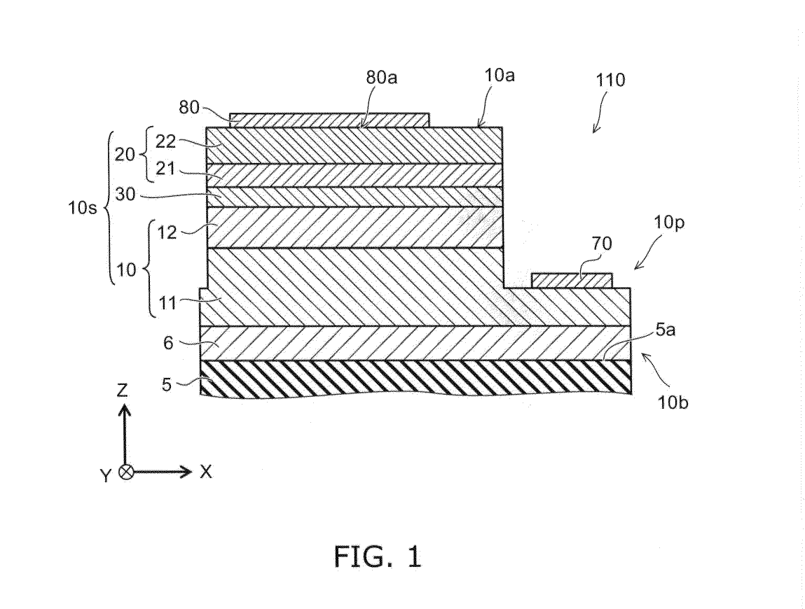

FIG. 1 is a schematic cross sectional diagram showing a semiconductor light emitting device of a first embodiment.

As shown in FIG. 1, a semiconductor light emitting device 110 of the embodiment includes a semiconductor stacked unit 10s, and a metal layer 80. The semiconductor stacked unit 10s includes a light emitting layer 30 including nitride semiconductor. The semiconductor stacked unit 10s includes nitride semiconductor. The metal layer 80 is in contact with the semiconductor stacked unit 10s, and includes Ag. The metal layer 80 is a silver layer (Ag layer). The metal layer 80 is, for example, a silver electrode. The metal layer 80 may be a layer including only Ag. Note that, the metal layer 80 may include Ag to which elements such as In, Cu, Al and the like are added. A content of element other than Ag is desirably not less than 0 at. % (atomic percent) and not more than 10 at. %, further desirably, not less than 0 at. % and not more than 1 at. %, further desirably, not less than 0 at. % and not more than 0.5 at. %. A portion within the metal layer 80 that is in contact with the semiconductor stacked unit 10s (portion including an interface 80a of the semiconductor stacked unit 10s and the metal layer 80) is an Ag film.

The semiconductor stacked unit 10s for example includes a first conductivity type first semiconductor layer 10 and a second conductivity type second semiconductor layer 20, and the light emitting layer 30. The light emitting layer 30 is provided between the first semiconductor layer 10 and the second semiconductor layer 20.

For example, the first conductivity type is an n-type, and the second conductivity type is a p-type. However, the embodiment is not limited to this, and the first conductivity type may be the p-type, and the second conductivity type may be the n-type. Hereinbelow, a case in which the first conductivity type is the n-type, and the second conductivity type is the p-type will be described.

Here, a direction extending from the first semiconductor layer 10 toward the second semiconductor layer 20 will be termed a Z-axis direction. One direction perpendicular to the Z-axis direction will be termed an X-axis direction. A direction perpendicular to the Z-axis direction and the X-axis direction will be termed a Y-axis direction.

The metal layer 80 contacts the semiconductor layer. In this example, the metal layer 80 contacts the second semiconductor layer 20. The semiconductor stacked unit 10s includes the light emitting layer 30 including a nitride semiconductor, the semiconductor layer (second semiconductor layer 20) including Ga stacked with the light emitting layer 30. The Z-axis direction corresponds to a stacking direction. The Z-axis direction is a direction from the light emitting layer 30 toward the second semiconductor layer 20. The Z-axis direction is a direction from the second semiconductor layer 30 toward the metal layer 80.

The first semiconductor layer 10, the second semiconductor layer 20, and the light emitting layer 30 include nitride semiconductor.

As shown in FIG. 1, the semiconductor light emitting device 110 may further include a substrate 5 and a buffer layer 6. The substrate 5 has a main surface 5a (first surface). The first semiconductor layer 10 is disposed between the main surface 5a of the substrate 5 and the light emitting layer 30. The buffer layer 6 is disposed between the main surface 5a of the substrate 5 and the first semiconductor layer 10.

A substrate configured for example of sapphire is used as the substrate 5. The main surface 5a of the substrate 5 is a (0001) plane, that is, a c plane. The main surface 5a of the substrate 5 may be inclined at an angle for example of 5 degrees or less with respect to the (0001) plane. For example, Alₓ₀Ga₁₋ₓ₀N (0≦x0≦1) layer is used as the buffer layer 6.

The first semiconductor layer 10 for example includes a first n-side layer 11 and a second n-side layer 12. The second n-side layer 12 is provided between the first n-side layer 11 and the light emitting layer 30. The first n-side layer 11 functions as an n-type contact layer. The second n-side layer 12 functions as an n-type guiding layer. For the first n-side layer 11, for example, a GaN layer and the like in which n-type impurities (for example, silicon and the like) are added at a high concentration is used. For the second n-side layer 12, for example, a GaN layer and the like in which the n-type impurities are added at a concentration lower than the first n-side layer 11 is used.

The second semiconductor layer 20 includes a first p-side layer 21, and a second p-side layer 22. The first p-side layer 21 is provided between the second p-side layer 22 and the light emitting layer 30. The first p-side layer 21 functions for example as an electron over-flow preventing layer (suppressing layer). The second p-side layer 22 functions as a p-type contact layer. For the first p-side layer 21, for example, an AlGaN layer and the like in which p-type impurities (for example, magnesium) are added is used. For the second p-side layer 22, a GaN layer and the like in which the p-type impurities are added at a high concentration is used. That is, the impurity concentration of the second p-side layer 22 is higher than the impurity concentration of the first p-side layer 21.

The semiconductor light emitting device 110 further includes an opposing side electrode 70. The opposing side electrode 70 is electrically connected with the first semiconductor layer 10 (specifically, the first n-side layer 11 that is the n-type contact layer). For the opposing side electrode 70, for example, a stacked film of a Ti film, a Pt film, and an Au film is used.

The metal layer 80 is electrically connected with the second semiconductor layer 20 (specifically, the second p-side layer 22 that is the p-type contact layer).

A current is supplied to the light emitting layer 30 through the first semiconductor layer 10 and the second semiconductor layer 20 by a voltage applied between the opposing side electrode 70 and the metal layer 80, and light (emitted light) is discharged from the light emitting layer 30.

The light emitting layer 30 for example discharges at least one of ultraviolet, violet, blue, and green lights. That is, a wavelength (dominant wavelength) of the emitted light discharged from the light emitting layer 30 is 360 nanometers (nm) or more and 580 nm or less.

In this specific example, at a first main surface 10a on a side of the second semiconductor layer 20 of the semiconductor stacked unit 10s, a part of the first semiconductor layer 10, a part of the light emitting layer 30, and a part of the second semiconductor layer 20 are removed.

The semiconductor stacked unit 10s includes the first main surface 10a on the second semiconductor layer 20 side, and a second main surface 10b on a side of the first semiconductor layer 10. The second main surface 10b is a surface on an opposite side of the first main surface 10a in the semiconductor stacked unit 10s. The first semiconductor layer 10 is exposed at the first main surface 10a of the semiconductor stacked unit 10s. The interface 80a between the semiconductor stacked unit 10s and the metal layer 80 corresponds to the first main surface 10a.

That is, the light emitting layer 30 is provided between a part of the first semiconductor layer 10 and the second semiconductor layer 20. On the first main surface 10a side, the opposing side electrode 70 is provided in contact with the first semiconductor layer 10. On the first main surface 10a side, the metal layer 80 is provided in contact with the second semiconductor layer 20. The substrate 5 and the buffer layer 6 are provided on the second main surface 10b of the semiconductor stacked unit 10s.

The light emitting layer 30 has a single quantum well (SQW) structure or a multi quantum well (MQW) structure.

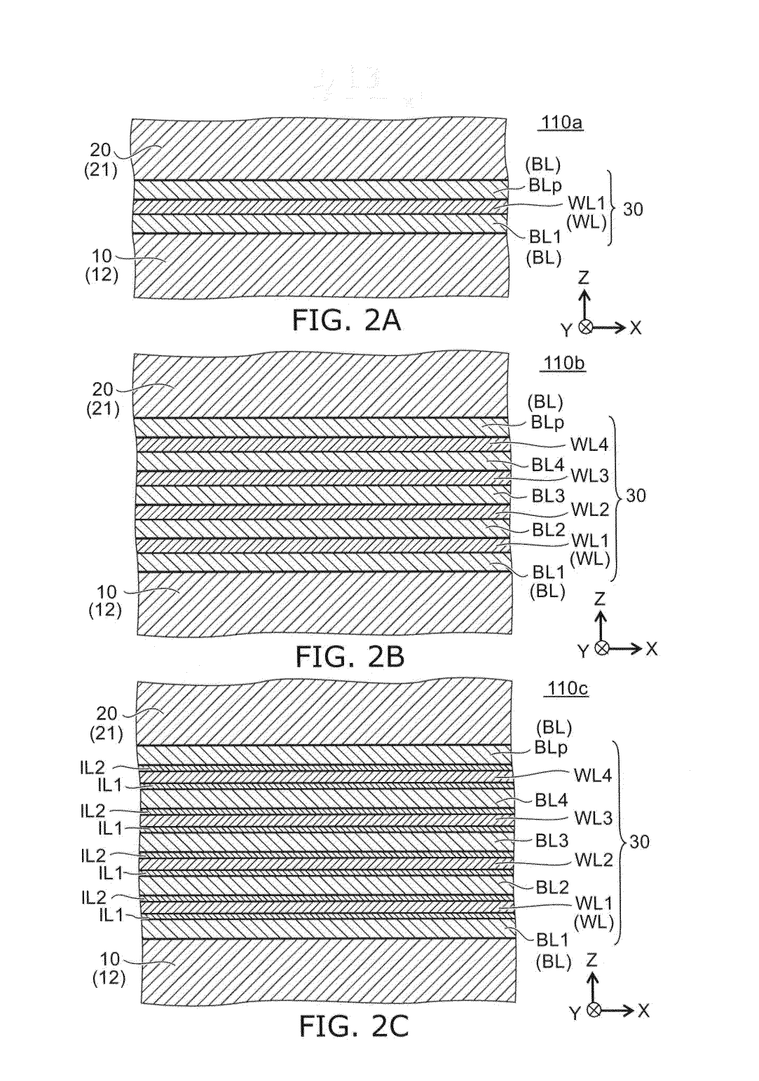

FIGS. 2A to 2C are schematic cross sectional diagrams showing a part of the semiconductor light emitting device of the first embodiment.

These drawings are schematic diagrams showing examples of the structure of the light emitting layer 30.

As shown in FIG. 2A, in a semiconductor light emitting device 110a of the embodiment, the light emitting layer 30 has the SQW structure. That is, the light emitting layer 30 includes a barrier layer BL (first barrier layer BL1), a p-side barrier layer BLp, and a well layer WL (first well layer WL1) provided between the first barrier layer BL1 and the p-side barrier layer BLp.

Note that, in the description of the application, “stacked” refers to a case of directly being layered, but also includes a case of being layered with another layer being intervened. For example, as will be described later, another layer may be provided between the first barrier layer BL1 and the first well layer WL1, and between the first well layer WL1 and the p-side barrier layer BLp.

As shown in FIG. 2B, in a semiconductor light emitting device 110b of the embodiment, the light emitting layer 30 has the MQW structure. That is, the light emitting layer 30 includes a plurality of barrier layers (in this example, first to fourth barrier layers BL1 to BL4 and p-side barrier layer BLp) stacked along the Z-axis direction, and well layers (first to fourth well layers WL1 to WL4) provided respectively between the plurality of barrier layers. In the example, although four layers of the well layer are provided, a number of the well layer is voluntary.

Accordingly, the light emitting layer 30 further includes, in a case of an integer N of 2 or more, an Nth barrier layer provided on an opposite side of a (N−1)th barrier layer of a (N−1)th well layer WL, and an Nth well layer provided on an opposite side of the (N−1)th well layer of the Nth barrier layer.

As shown in FIG. 2C, in a semiconductor light emitting device 110c of the embodiment, the light emitting layer 30 further includes intermediate layers provided respectively between the barrier layers and the well layers. That is, the light emitting layer 30 further includes a first intermediate layer IL1 provided between the (N−1)th barrier layer and the (N−1)th well layer, and a second intermediate layer IL2 provided between the (N−1)th well layer and the Nth barrier layer. Further, the second intermediate layer IL2 is provided between the Nth well layer and the p-side barrier layer BLp. Note that, the first intermediate layer IL1 and the second intermediate layer IL2 are provided as needed, and may be omitted. Further, the first intermediate layer IL1 may be provided while the second intermediate layer IL2 is omitted. Further, the second intermediate layer IL2 may be provided while the first intermediate layer IL1 is omitted.

For the barrier layers (for example, first to fourth barrier layers BL1 to BL4; Nth barrier layer), for example, Inₓ₁Al_{y1}Ga_{1-x1-y1}N (0≦x1<1, 0≦y1<1, x1+y1≦1) may be used. For the barrier layers, for example, In_{0.02}Al_{0.33}Ga_{0.65}N may be used. Thickness of the barrier layers may for example be 12.5 nm.

For the p-side barrier layer BLp, for example, Inₓ₂Al_{y2}Ga_{1-x2-y2}N (0≦x2<1, 0≦y2<1, x2+y2≦1) may be used. For the p-side barrier layer BLp, for example, In_{0.02}Al_{0.33}Ga_{0.65}N may be used. Thickness of the barrier layer may for example be 12.5 nm.

For the well layers (first to fourth well layers WL1 to WL4; Nth well layer), for example, Inₓ₃Al_{y3}Ga_{1-x3-y3}N (0<x3≦1, 0≦y3<1, x3+y3≦1) may be used. For the well layers, for example, In_{0.15}Ga_{0.85}N may be used. Thickness of the well layers may for example be 2.5 nm.

A composition ratio of In contained in the well layers (rate of a number of In atoms among group III elements) is higher than a composition ratio of In contained in the barrier layers (first to fourth barrier layers BL1 to BL4; Nth barrier layer, and p-side barrier layer BLp) (rate of a number of In atoms among group III elements). Due to this, band gap energy in the barrier layers can be made larger than band gap energy in the well layers.

For the first intermediate layers IL1, for example, Inₓ₄Ga₁₋ₓ₄N (0≦x4<1) may be used. For the first intermediate layers IL1, for example, In_{0.02}Ga_{0.98}N may be used. Thickness of the first intermediate layers IL1 may for example be 0.5 nm.

For the second intermediate layers IL2, for example, Inₓ₅Ga₁₋ₓ₅N (0≦x5<1) may be used. For the second intermediate layers IL2, for example, In_{0.02}Ga_{0.98}N may be used. Thickness of the second intermediate layers IL2 may for example be 0.5 nm.

Composition ratio of In contained in the well layers (rate of the number of In atoms among group III elements) is higher than a composition ratio of In contained in the first intermediate layers IL1 and the second intermediate layers IL2 (rate of the number of In atoms among group III elements). Due to this, band gap energy in the first intermediate layers IL1 and the second intermediate layers IL2 can be made larger than the band gap energy in the well layers.

Note that, the first intermediate layers IL1 may be regarded as parts of the barrier layers. Further, the second intermediate layers IL2 may be regarded as parts of the barrier layers. That is, the barrier layers stacked with the well layers may include a plurality of layers having different compositions.

Note that, in the SQW structure shown as an example in FIG. 2A, the first intermediate layer IL1 and the second intermediate layer IL2 may be provided. In this case, the first intermediate layer IL1 is provided between the first barrier layer BL1 and the first well layer WL1, and the second intermediate layer IL2 is provided between the first well layer WL1 and the p-side barrier layer BLp.

The above are examples of a configuration of the light emitting layer 30, so the embodiment is not limited to these, and various modification may be made to used materials and thicknesses of the barrier layers, the p-side barrier layer BLp, the well layers, the first intermediate layers IL1, and the second intermediate layers IL2. Note that, as described above, the barrier layers, the p-side barrier layer BLp, the well layers, the first intermediate layers IL1, and the second intermediate layers IL2 contain nitride semiconductor.

Hereinbelow, in regards to the embodiment, a semiconductor light emitting device 110 including the semiconductor light emitting devices 110a to 110c will be described. The semiconductor light emitting device 110 can be manufactured by the following method.

For example, nitride semiconductor layers that are to be the semiconductor stacked unit 10s are successively grown on the sapphire substrate 5 for crystal growth by using a metal organic chemical vapor deposition (MOCVD) method. Thereafter, for example, the semiconductor stacked unit 10s is processed, whereby a part of the first semiconductor layer 10 is exposed, and the opposing side electrode 70 is formed on the first semiconductor layer 10.

On the other hand, an Ag film that is to be the metal layer 80 is formed on the second p-side layer 22 (p-type contact layer) of the semiconductor stacked unit 10s. Next, after having performed annealing (thermal treatment) at 800° C. in a nitrogen atmosphere, annealing for example at 300° C. is performed in an oxygen atmosphere. Due to this, the metal layer 80 is formed. Note that, an order of forming the metal layer 80 and forming the opposing side electrode 70 may be switched.

Accordingly, by performing on the Ag film the low temperature annealing in the oxygen atmosphere after the high temperature annealing in the nitrogen atmosphere, a semiconductor light emitting device having an electrode with low contact resistance and high reflectivity can be obtained.

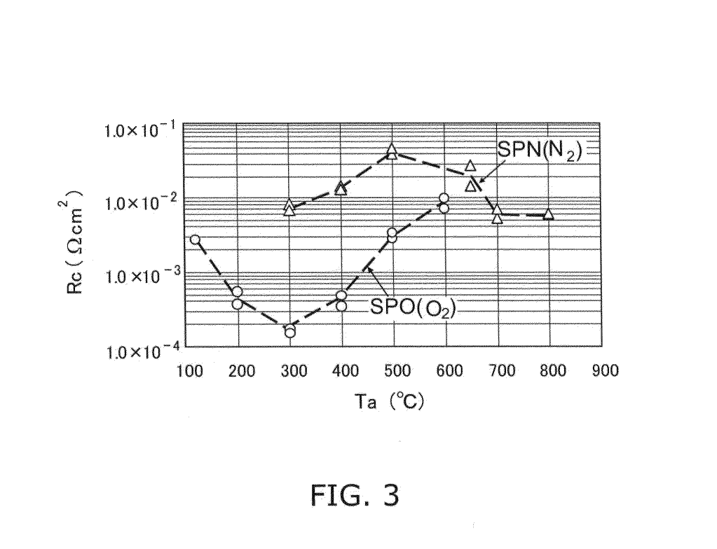

FIG. 3 is a diagram of a graph showing characteristics of the semiconductor light emitting device.

FIG. 3 shows a contact resistance Rc (specific contact resistivity) between the Ag film and the second semiconductor layer 20 in a sample to which annealing is performed under various conditions on the Ag film formed on the second semiconductor layer 20. In this example, annealing time is 1 min (minute). A horizontal axis is a temperature Ta (° C.) of the annealing, and a vertical axis is the contact resistance Rc (Ωcm²). In FIG. 3, an oxygen annealing sample group SPO to which annealing in the oxygen atmosphere is performed on the Ag film, and a nitride annealing sample group SPN to which annealing in the nitrogen atmosphere is performed on the Ag film are indicated.

As shown in FIG. 3, the contact resistance Rc of the oxygen annealing sample group SPO that annealed the Ag film in the oxygen atmosphere is 1.5×10⁻⁴ Ωcm² or more and 6×10⁻⁴ Ωcm² or less, when the annealing temperature Ta is 200° C. to 400° C. On the other hand, the contact resistance Rc of the nitrogen annealing sample group SPN that annealed the Ag film in the nitrogen atmosphere is 5×10⁻³ Ωcm² or more and 4×10⁻² Ωcm² or less. That is, the contact resistance Rc of the oxygen atmosphere annealing is lower than the contact resistance of the nitrogen atmosphere annealing.

Reflectivity of these samples is as follows. The reflectivity with respect to light of 450 nm of the samples to which the annealing had been performed under various conditions is measured, and a difference (R0−R1) between the reflectivity R1 thereof and reflectivity R0 of an unannealed Ag film is set to be a reflectivity drop level ΔRf. In a sample SPO300 annealed in the oxygen atmosphere at 300° C., the reflectivity drop level ΔRf is about 6%. On the other hand, in a sample SPN300 annealed in the nitrogen atmosphere at 300° C., the reflectivity drop level ΔRf is substantially 0, and no change is observed.

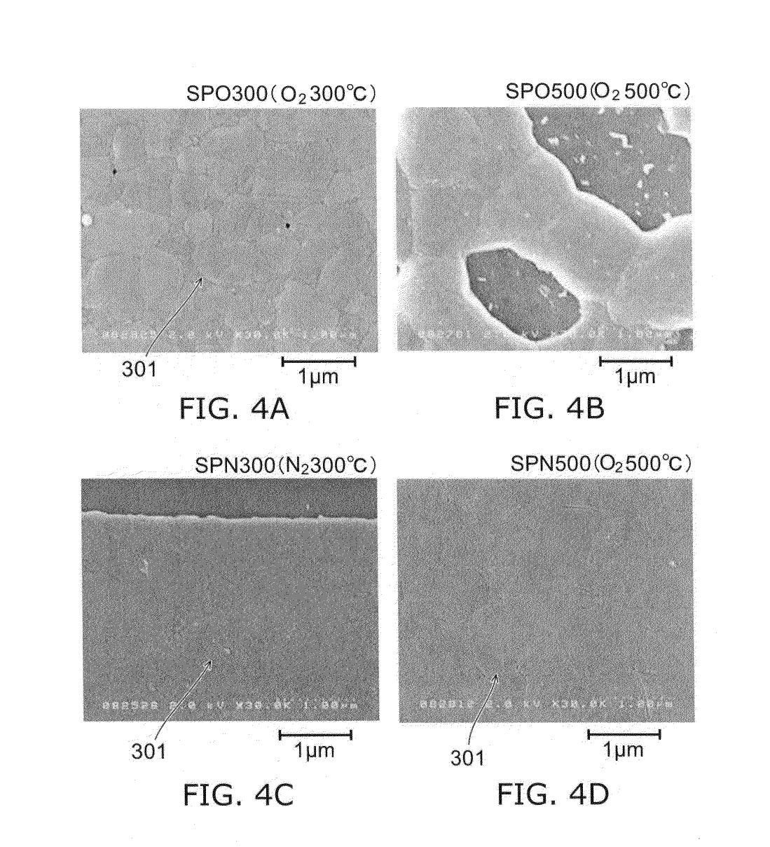

FIG. 4A to FIG. 4D are diagrams of electron micrographs showing examples of the characteristics of the semiconductor light emitting device.

These drawings respectively show SEM picture images of the sample SPO300 annealed in the oxygen atmosphere at 300° C., a sample SPO500 annealed in the oxygen atmosphere at 500° C., the sample SPN300 annealed in the nitrogen atmosphere at 300° C., and a sample SPN500 annealed in the nitrogen atmosphere at 500° C., respectively. The SEM picture images are images that were taken along the Z-axis direction, so they correspond to observing a X-Y plane.

As shown in FIG. 4A and FIG. 4B, in the oxygen atmosphere annealing, grains 301 are grown three-dimensionally. Further, at 500° C., pores are generated. It is assumed that Ag migration occurs in the oxygen atmosphere annealing.

On the other hand, as shown in FIG. 4C and FIG. 4D, in the nitrogen atmosphere annealing, grains 301 are grown two-dimensionally while maintaining flat surfaces. It is assumed that the migration is suppressed under this annealing condition.

The above difference in the changes of the reflectivitys in the oxygen atmosphere and the nitrogen atmosphere is assumed as being related to morphology of the Ag film as above, that is, to degrees of the migration.

Accordingly, although low contact resistance Rc is obtained in the oxygen atmosphere annealing, the reflectivity thereof is low. On the other hand, in the nitrogen atmosphere annealing, although the constant resistance Rc is high, high reflectivity can be maintained.

The inventor of the application produced various samples, to the Ag films of which the annealing in the nitrogen atmosphere is performed, and the annealing in the oxygen atmosphere is further performed thereafter. As a result, a discovery has been made that low contact resistance Rc and high reflectivity (small reflectivity drop level ΔRf) can be obtained under a specific condition.

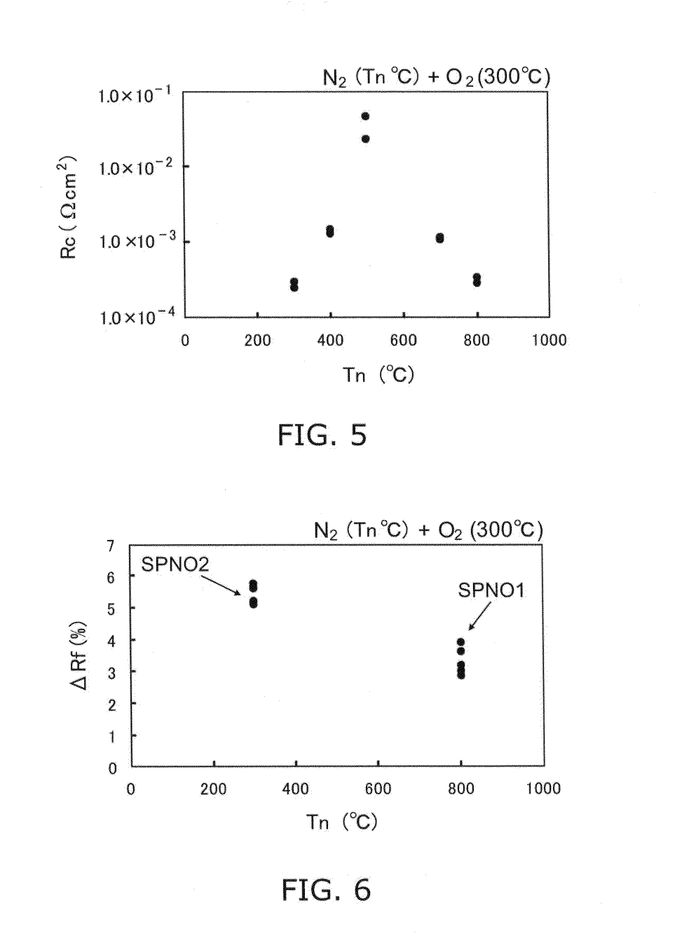

FIG. 5 is a diagram of a graph showing characteristics of the semiconductor light emitting device.

FIG. 5 shows the contact resistance Rc of samples, to the Ag films of which the nitrogen atmosphere annealing is performed and thereafter the oxygen atmosphere annealing is performed at 300° C. is further performed. A horizontal axis is a temperature Tn (° C.) of the annealing in the nitrogen atmosphere, and a vertical axis is the contact resistance Rc (Ωcm²).

As shown in FIG. 5, when the temperature Tn of the annealing in the nitrogen atmosphere is 700° C. or more and 800° C. or less, or when it is 300° C. or more and 400° C. or less, the contact resistance Rc comes to be at 1.5×10⁻⁴ Ωcm² or more and 1.5×10⁻³ Ωcm² or less. When the temperature Tn of the annealing in the nitrogen atmosphere is 500° C. or more and 600° C. or less, the contact resistance Rc is significantly high, namely 2.0×10⁻² Ωcm² or more. When the temperature Tn of the annealing is 600° C., the contact resistance Rc is too high to be measured.

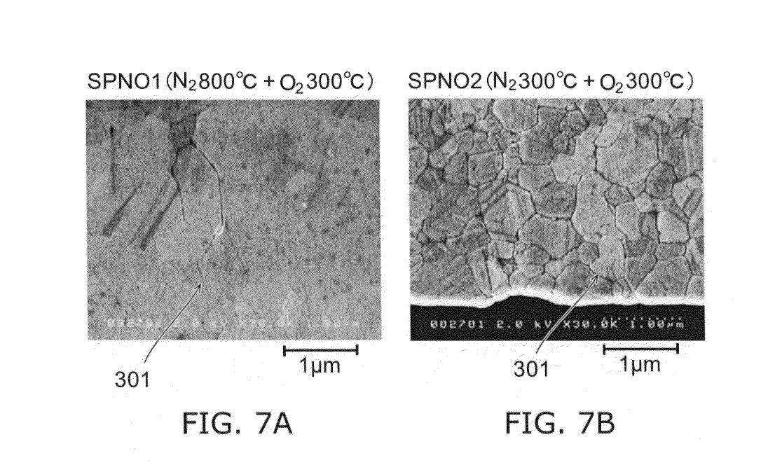

FIG. 6 is a diagram of a graph showing characteristics of the semiconductor light emitting device.

FIG. 6 shows the change in the reflectivity of the samples, to the Ag films of which the nitrogen atmosphere annealing is performed and thereafter the oxygen atmosphere annealing is further performed at 300° C. A horizontal axis is a temperature Tn (° C.) of the annealing in the nitrogen atmosphere, and a vertical axis is the reflectivity drop level ΔRf (%).

As shown in FIG. 6, when the temperature Tn of the annealing in the nitrogen atmosphere is 300° C., the reflectivity drop level ΔRf is large, namely, about 6%. Contrary to this, when the temperature Tn of the annealing in the nitrogen atmosphere is 800° C., the reflectivity drop level ΔRf is small, namely, about 3%.

Accordingly, low contact resistance Rc and high reflectivity (small reflectivity drop level ΔRf) can be obtained by annealing the Ag film in the nitrogen atmosphere at a high temperature (for example, 700° C. or more, and for example, 800° C. or less), and thereafter annealing the Ag film in the oxygen atmosphere at a low temperature (for example, about 300° C.).

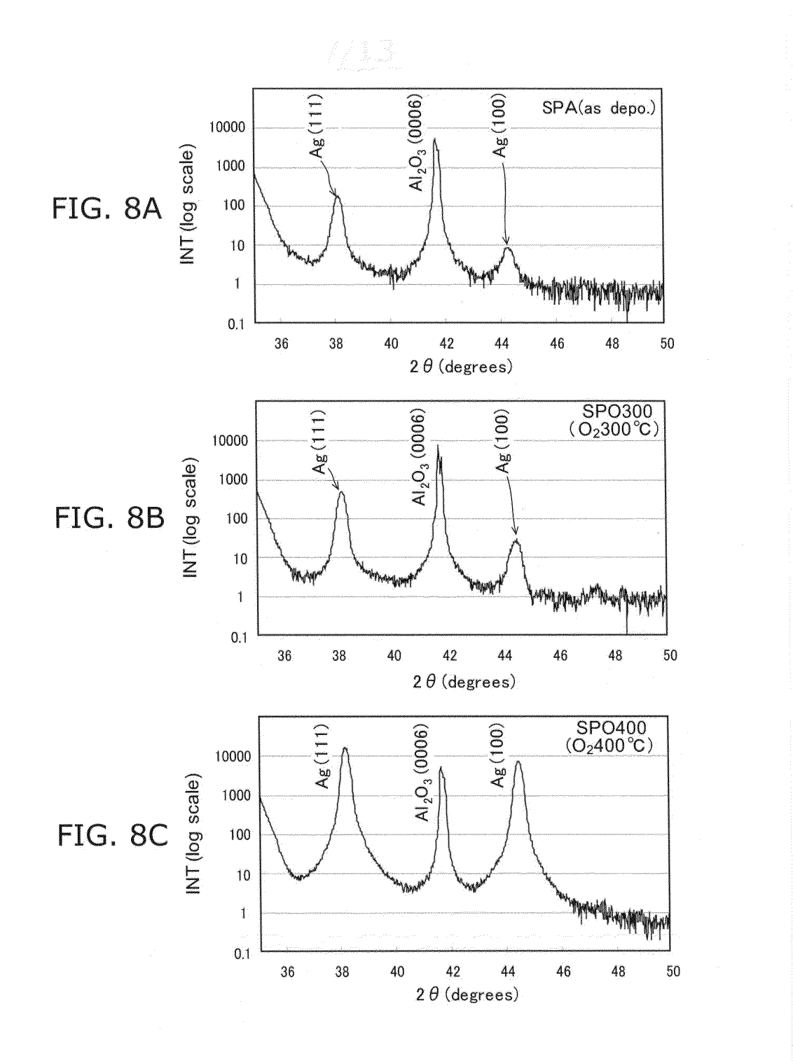

FIG. 7A and FIG. 7B are diagrams of electron micrographs showing the characteristics of the semiconductor light emitting device.

FIG. 7A is an SEM picture image of a sample SPNO1 to which annealing in the oxygen atmosphere at 300° C. is performed after annealing in the nitrogen atmosphere at 800° C. FIG. 7B is an SEM picture image of a sample SPNO2 to which annealing in the oxygen atmosphere at 300° C. is performed after annealing in the nitrogen atmosphere at 300° C. The SEM picture images are images that were taken along the Z-axis direction, so they correspond to observing the X-Y plane.

As shown in FIG. 7A, in the sample SPNO1, large grains 301 are grown two-dimensionally. It is assumed that the sample SPNO1 having a small reflectivity drop level ΔRf of about 3% is related to the grains 301 observed by the SEM being large and having flat surfaces.

On the other hand, as shown in FIG. 7B, in the sample SPNO2, diameters of grains 301 are small. It is assumed that the sample SPNO2 having a large reflectivity drop level ΔRf is related to the grains 301 being small and having rough surfaces.

In the sample SPNO1, an average area of the plurality of grains 301 observed by the SEM is 5 μm² or more and 100 μm² or less. An average area of the plurality of grains 301 is an area of the grains 301 in a plane which is perpendicular to the stacking direction from the second semiconductor layer 20 toward the metal layer 80 (for example, in a plane parallel to the interface 80a, namely the X-Y plane). High reflectivity is obtained when relatively large grains 301 exist.

Relatively large grains 301 existing and high reflectivity obtained in the sample of the sample SPNO1 are assumed to be attributed to the fully crystallized Ag film due to the annealing in the nitrogen atmosphere at a high temperature, and the migration after that being suppressed in the oxygen atmosphere. Contrary to this, the grains 301 being small and the reflectivity being low in the sample of the sample SPNO2 are assumed to be attributed to the partially crystallized Ag film due to the annealing in the nitrogen atmosphere at a low temperature, by which the migration after that in the oxygen atmosphere is easily caused.

Accordingly, in the semiconductor light emitting device 110 of the embodiment, the metal layer 80 that is the Ag film can include the plurality of grains 301. Further, the average area of the plurality of grains 301 is 5 μm² or more and 100 μm² or less. Due to this, high reflectivity can be obtained.

Further, in the semiconductor light emitting device 110, the specific contact resistivity (contact resistance Rc) between the metal layer 80 and the semiconductor stacked unit 10s (more specifically the second semiconductor layer 20) is 1.5×10⁻⁴ Ωcm² or more and 1.5×10⁻³ Ωcm² or less. Due to this, in the semiconductor light emitting device 110, an electrode (metal layer 80) with low contact resistance and high reflectivity can be obtained.

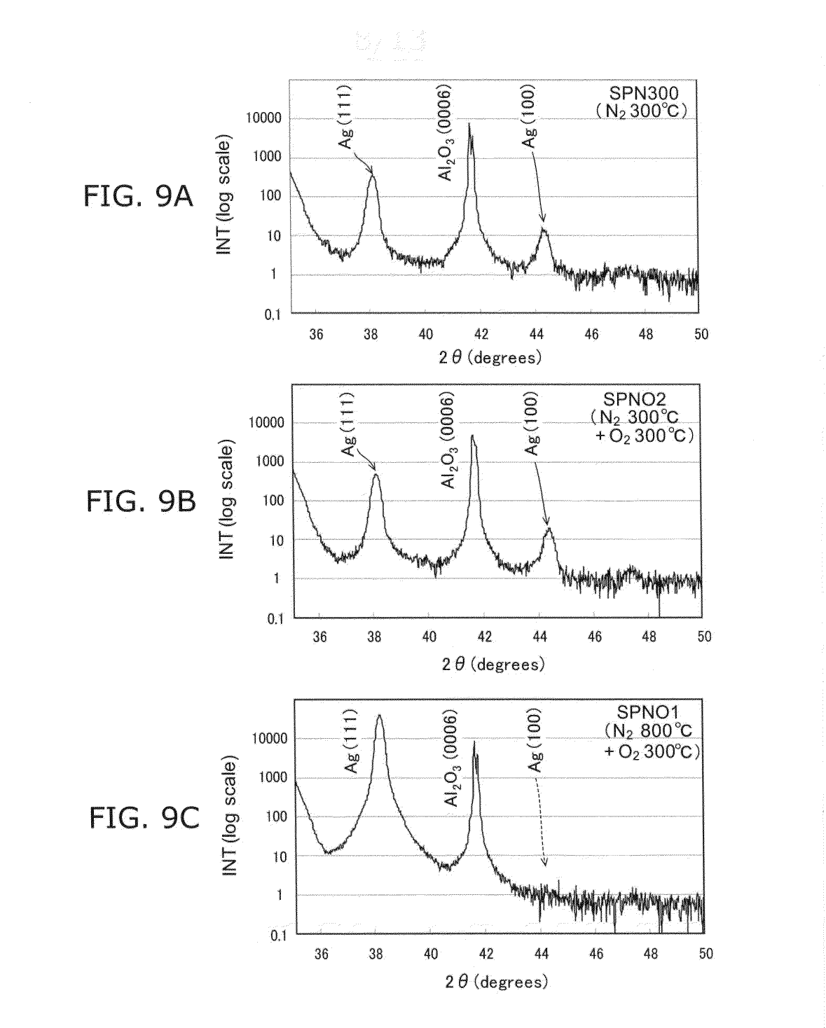

FIG. 8A to FIG. 8C and FIG. 9A to FIG. 9C are diagrams of X-ray diffraction profiles showing the characteristics of the semiconductor light emitting device.

FIG. 8A shows the X-ray diffraction (XRD) profile of a sample SPA on which an Ag film is formed and annealing is not performed. FIG. 8B, FIG. 8C, FIG. 9A, FIG. 9B, and FIG. 9C show the XRD profiles of a sample SPO300 (annealed in oxygen atmosphere at 300° C.), a sample SPO400 (annealed in oxygen atmosphere at 400° C.), a sample SPN300 (annealed in nitrogen atmosphere at 300° C.), a sample SPNO2 (annealed in nitrogen atmosphere at 300° C.+annealed in oxygen atmosphere at 300° C.), and a sample SPNO1 (annealed in nitrogen atmosphere at 800° C.+annealed in oxygen atmosphere at 300° C.), respectively. A horizontal axis thereof is a doubled inclination angle θ upon measurement (2θ (degrees)), and a vertical axis is a logarithm (relative value) of an intensity INT.

As shown in FIG. 9A, in the unannealed sample SPA, a peak belonging to a (111) plane of Ag is obtained when 2θ is around about 38 degrees, and a peak belonging to a (100) plane of Ag is obtained when 2θ is around about 44 degrees. Note that, in such samples, a peak belonging to a (0006) plane of Al₂O₃ that is the substrate is also obtained when 2θ is about 42 degrees. Hereinbelow, focus will be made to the peak belonging to the (111) plane of Ag (2θ being about 38 degrees) and the peak belonging to the (100) plane of Ag (2θ being about 44 degrees).

As shown in FIG. 8B, FIG. 8C, FIG. 9A, and FIG. 9B, peaks belonging to the (100) plane of Ag are relatively high in the sample SPO300, the sample SPO400, the sample SPN300, and the sample SPNO2. Heights of the peaks belonging to the (100) plane of Ag are larger than 3% of heights of the peaks belonging to the (111) plane of Ag. Here, for example, an average of the intensity INT in a range of 2θ being 46 degrees or more and 48 degrees or less will be used as a reference value (background value). That is, the heights of the peaks belonging to the (100) plane of Ag come to be at a ratio of the intensity INT in the case of the 2θ being 44 degrees with respect to the reference value (average of the intensity INT in the case of the 2θ being 46 degrees or more and 48 degrees or less). Further, the heights of the peaks belonging to the (100) plane of Ag come to be at a ratio of the intensity INT in the case of the 2θ being 38 degrees with respect to the reference value.

On the other hand, as shown in FIG. 9C, in the sample SPNO1, the peak belonging to the (100) plane of Ag is very low. That is, a height of the peak belonging to the (100) plane of Ag is smaller than 3% of a height of the peak belonging to the (111) plane of Ag. This corresponds to the metal layer 80 having a preferred orientation toward <111> in the sample SPNO1. In the case of having the preferred orientation toward <111>, this means that there are more portions oriented in a <111> direction than portions oriented in directions other than the <111> direction. In the case of having the preferred orientation toward <111>, in an analysis using an X-ray diffraction analysis, a peak belonging to a plane other than the (111) plane (specifically, the (100) plane) is at or less than 3% of the height of the peak belonging to the (111) plane. In the metal layer 80, the state of having the preferred orientation toward <111> can also be evaluated for example by an analysis using an electron beam.

Accordingly, it has been found that a crystal structure is specific in the metal layer 80 (Ag film) having the low contact resistance and high reflectivity. That is, the low contact resistance Rc and high reflectivity (small reflectivity drop level ΔRf) are obtained when the height of the peak belonging to the (100) plane of Ag film is at or less than 3% of the height of the peak belonging to the (111) plane of Ag.

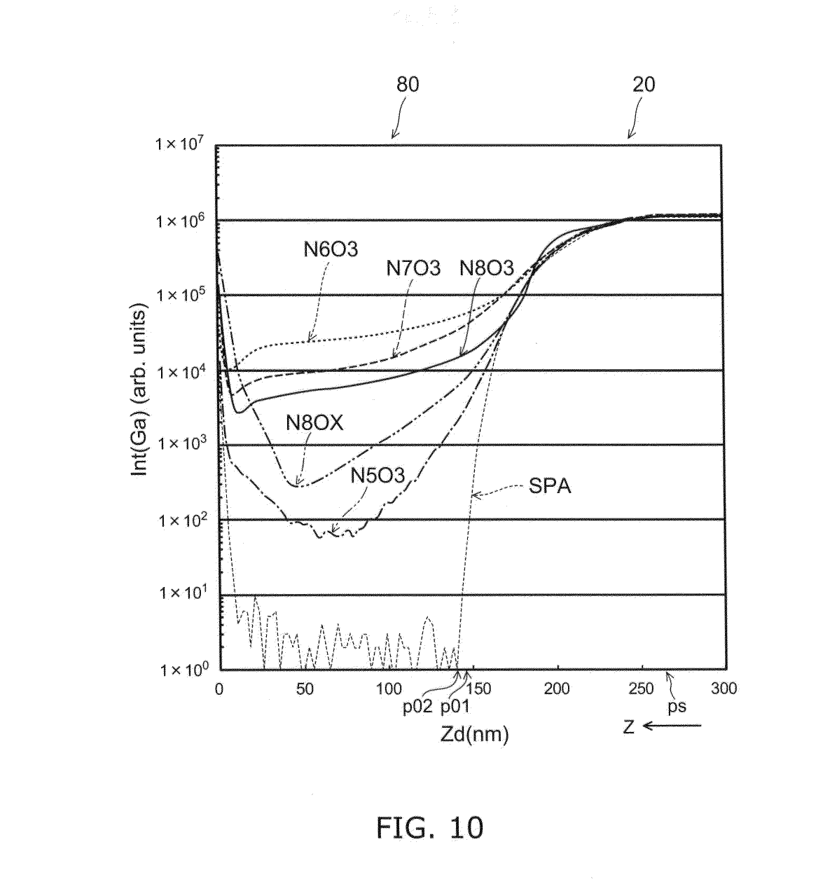

FIG. 10 is a diagram of a graph showing characteristics of the semiconductor light emitting device.

FIG. 10 shows a profile of SIMS (secondary ion mass spectrometry) of samples annealed in the nitrogen atmosphere at different temperatures of 500° C. to 800° C. FIG. 10 shows an intensity distribution of Ga atoms in the second semiconductor layer and the metal layer 80 (Ag layer). The horizontal axis of FIG. 1 represents a depth Zd (a position along the Z-axis direction). The vertical axis represents a detected intensity Int (Ga) (relative value) of Ga atoms and is logarithmic.

For a sample N5O3, after annealing at 500° C. in the nitrogen atmosphere, annealing at 300° C. is performed in the oxygen atmosphere.

For a sample N6O3, after annealing at 600° C. in the nitrogen atmosphere, annealing at 300° C. is performed in the oxygen atmosphere.

For a sample N7O3, after annealing at 700° C. in the nitrogen atmosphere, annealing at 300° C. is performed in the oxygen atmosphere.

For a sample N8O3, after annealing at 800° C. in the nitrogen atmosphere, annealing at 300° C. is performed in the oxygen atmosphere. The sample N8O3 corresponds to the sample SPNO1 described above.

FIG. 10 also illustrates the characteristics of the sample SPA having an Ag film formed without annealing. FIG. 10 also illustrates the characteristics of a sample N8OX. For the sample N8OX, annealing is performed at 800° C. in the nitrogen atmosphere, and annealing is not performed in the oxygen atmosphere.

As shown in FIG. 10, for the sample SPA without annealing, the detected intensity Int (Ga) of Ga atoms in the metal layer 80 (Ag layer) is less than about 1×10¹. The detected intensity of Ga atoms in the second semiconductor layer 20 is about 1×10⁶. In the sample SPA without annealing, a Ga concentration is lower than 1×10⁻⁵ times of a Ga concentration in the second semiconductor layer 20. In the sample SPA, Ga is not substantially detected from the metal layer 80.

Annealing causes Ga to be detected from the metal layer 80.

In the sample N8OX (annealed at 800° C. in nitrogen atmosphere, not annealed in oxygen atmosphere), the detected intensity Int (Ga) of Ga atoms in the metal layer 80 is, for example, approximately 3×10² to 3×10³.

In the sample N5O3 (after annealed at 500° C. in nitrogen atmosphere, annealed at 300° C. in oxygen atmosphere), the detected intensity Int (Ga) of Ga atoms in the metal layer 80 is, for example, approximately 7×10¹ to 2×10³.

In the sample N6O3 (after annealed at 600° C. in nitrogen atmosphere, annealed at 300° C. in oxygen atmosphere), the detected intensity Int (Ga) of Ga atoms in the metal layer 80 is, for example, approximately 1×10⁴ to 5×10⁴.

In the sample N7O3 (after annealed at 700° C. in nitrogen atmosphere, annealed at 300° C. in oxygen atmosphere), the detected intensity Int (Ga) of Ga atoms in the metal layer 80 is, for example, approximately 5×10³ to 3×10⁴.

In the sample N8O3 (after annealed at 800° C. in nitrogen atmosphere, annealed at 300° C. in oxygen atmosphere), the detected intensity Int (Ga) of Ga atoms in the metal layer 80 is, for example, approximately 3×10³ to 2×10⁴.

Thus, when the temperature Tn of annealing in the nitrogen atmosphere is low to be 500° C., the Ga concentration in the metal layer 80 is low. When the annealing temperature Tn in the nitrogen atmosphere is increased from 500° C. to 600° C., the Ga concentration in the metal layer 80 increases drastically. In the annealing temperature Tn in the nitrogen atmosphere of 700° C. to 800° C., the Ga concentration in the metal layer 80 is lower than a value at 600° C.

The Ga concentration in the metal layer 80 is naturally low at the annealing temperature Tn in the nitrogen atmosphere being low to be 500° C. On the other hand, when the annealing temperature Tn in the nitrogen atmosphere is 600° C., the Ga concentration in the metal layer 80 is extremely high, and when the annealing temperature Tn in the nitrogen atmosphere is 700° C. or more, the Ga concentration in the metal layer 80 decreases. This is a phenomena firstly discovered in the present experiment.

As described in FIG. 5, when the annealing temperature Tn in the nitrogen atmosphere is not less than 700° C. and not more than 800° C., the low contact resistance Rc is obtained. When the annealing temperature Tn is not less than 500° C. and not more than 600° C., the contact resistance Rc is high. Particularly, at the annealing temperature of 600° C., the contact resistance is too high to be measured. As described in FIG. 3, for the sample N8OX without annealing in the oxygen atmosphere, the contact resistance Rc is about 6×10⁻³ (Ωcm⁻²) and is high.

There is a correlation between the relationship between the contact resistance Rc and the annealing temperature Tn shown in FIG. 5 and the relationship between the Ga concentration in the metal layer 80 and the annealing temperature Tn shown in FIG. 10.

That is, when the annealing temperature Tn is excessively low to be approximately 500° C., the Ga concentration in the metal layer 80 is low and the contact resistance Rc is high as well. When the annealing temperature Tn is approximately 600° C., the Ga concentration in the metal layer 80 is significantly high and the contact resistance Rc is also significantly high. When the annealing temperature Tn exceeds 600° C., and is not less than 700° C. and not more than 800° C., the Ga concentration in the metal layer 80 is moderate and the contact resistance Rc decreases.

In both cases of the Ga concentration in the metal layer 80 being too low and being too high, the contact resistance Rc increases. When the Ga concentration in the metal layer 80 is in a moderate range, the low contact resistance Rc is obtained. It has not been known that there is an adequate range to obtain the low contact resistance Rc for the Ga concentration in the metal layer 80.

In SIMS analysis, the Ga concentration is detected as a relative value. As illustrated in FIG. 10, the Ga concentration varies in a region including an interface between the metal layer 80 and the second semiconductor layer 20. An example of a reference mark showing quantitatively the Ga concentration in the metal layer 80 is introduced.

As to the reference mark, the intensity of “Ga+N” is measured in addition to the intensity of Ga atom in the SIMS analysis in the region including the second semiconductor layer 20 and the metal layer (Ag layer). The intensity of “Ga+N” is, for example, a detected intensity of a complex of gallium atoms and nitrogen atoms. On the basis of the characteristics of the detected intensity of “Ga+N” (complex), a standard position in the region including the metal layer 80 and the second semiconductor layer 20 is defined. The Ga concentration in the metal layer 80 is defined on the basis of the standard position.

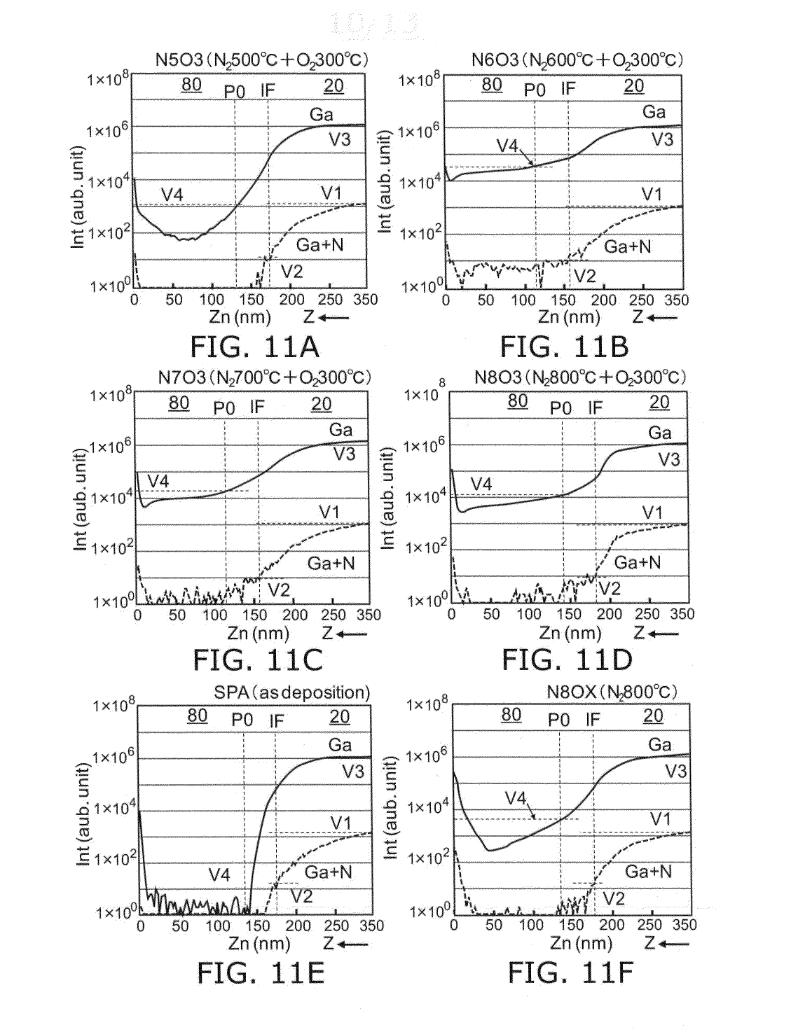

FIG. 11A to FIG. 11F are diagrams of graphs illustrating characteristics of the semiconductor light emitting devices.

FIG. 11A to FIG. 11F correspond to the sample N5O3, the sample N6O3, the sample N7O3, the sample N8O3, the sample SPA and the sample N8OX, respectively. These figures are examples of SIMS analysis results. The horizontal axis represents the depth Zd. The vertical axis represents the detected intensity of Ga atoms or the detected intensity of “Ga+N” (complex). The vertical axis represents the relative value and is logarithmic.

For example, as shown in FIG. 11A, the maximum value V1 of the detected intensity of “Ga+N” (complex) in the second semiconductor layer 20 is about 1.4×10³. A position along the depth Zd direction where the detected intensity “Ga+N” (complex) is 1/100 times of the maximum value V1 is taken as a first position IF. The first position IF may be considered to be the interface between the metal layer 80 and the second semiconductor layer 20. The first position IF is a position along the stacking direction from the second semiconductor 20 toward the metal layer 80 in the region including the second semiconductor layer 20 and the metal layer 80 (Ag layer). The detected intensity V2 of “Ga+N” (complex) at the first position IF is 1/100 times of the maximum value V1.

A position (second position) spaced from the first position IF by 40 nm along the Z-axis direction (stacking direction) in the metal layer 80 is taken as a concentration definition position P0. In the embodiment, a thickness of the metal layer 80 (Ag layer) is practically, for example, not less than 40 nm and not more than 1000 nm. Consequently, the second position (concentration definition position P0) spaced from the first position IF by 40 nm along the Z-axis direction (stacking direction) is placed in the metal layer 80. Thus, the second position (the concentration definition position P0) is introduced in the metal layer 80 (silver layer). Then, the distance between the second position and the first position IF is set to be 40 nm

On the other hand, the detected intensity of Ga atoms in the second semiconductor layer 20 is a detected intensity of Ga atoms at a position sufficiently spaced from the first position IF. For example, in examples of FIG. 11A to FIG. 11F, the detected intensity of Ga atoms in the second semiconductor layer 20 is nearly constant in a distance not less than 100 nm from the first position IF. The detected intensity of Ga atoms at a position sufficiently spaced from the first position IF is the maximum value V1 of the detected intensity of Ga atoms in the second semiconductor layer 20. For example, the maximum value V1 of the detected intensity of Ga atoms in the second semiconductor layer 20 is taken as the detected intensity of Ga atoms at the position spaced from the first position IF by 100 nm. In any examples, the maximum value V3 of the detected intensity of Ga atoms in the second semiconductor layer 20 is about 1×10⁶.

In respective samples, the detected intensities G4 of the Ga atoms at the concentration definition position P0 in the metal layer 80 are different one another.

In the sample N5O3, the detected intensity V4 of Ga atoms at the concentration definition position P0 is about 1.5×10³. In the sample N5O3, the detected intensity V4 is about 0.1% of the maximum value V3 of the detected intensity of Ga atoms in the second semiconductor layer 20.

In the sample N6O3, the detected intensity V4 of Ga atoms at the concentration definition position P0 is about 4.5×10⁴. In the sample N6O3, the detected intensity V4 is about 3.8% of the maximum value V3 of the detected intensity of Ga atoms in the second semiconductor layer 20.

In the sample N7O3, the detected intensity V4 of Ga atoms at the concentration definition position P0 is about 2.0×10⁴. In the sample N7O3, the detected intensity V4 is about 1.7% of the maximum value V3 of the detected intensity of Ga atoms in the second semiconductor layer 20.

In the sample N8O3, the detected intensity V4 of Ga atoms at the concentration definition position P0 is about 1.4×10⁴. In the sample N8O3, the detected intensity V4 is about 1.4% of the maximum value V3 of the detected intensity of Ga atoms in the second semiconductor layer 20.

In the sample SPA, the detected intensity V4 of Ga atoms at the concentration definition position P0 is about 2×10⁰.

In the sample N8OX, the detected intensity V4 of Ga atoms at the concentration definition position P0 is about 4.2×10³. In the sample N8OX, the detected intensity V4 is about 0.4% of the maximum value V3 of the detected intensity of Ga atoms in the second semiconductor layer 20.

Therefore, when using the definition like this, it is found that when the detected intensity V4 is higher than 0.4% and lower than 3.8% of the maximum value V3 of the detected intensity of Ga atoms in the second semiconductor layer 20, the low contact resistance Rc is obtained.

That is, in the embodiment, in SIMS analysis (secondary ion mass spectrometry analysis), the detected intensity V2 of the complex composed of gallium atoms and nitrogen atoms at the first position in the region including the second semiconductor layer 20 and the metal layer 80 (silver layer) along the stacking direction from the second semiconductor layer 20 toward the metal layer 80 is 1/100 times of the maximum value V1 of the detected intensity of the complex in the second semiconductor layer 20.

In the secondary ion mass analysis, the detected intensity V4 of Ga atoms at the second position (concentration definition position P0) in the distance from the first position IF by 40 nanometers in the metal layer 80 is higher than 0.4% and lower than 3.8% of the maximum value V3 of the detected intensity of Ga atoms in the second semiconductor layer 20.

This allows the low contact resistance to be obtained. It is desirable that the detected intensity V4 is not less than 1.4% of the maximum value V3 of the detected intensity of gallium atoms in the second semiconductor layer 20. It is desirable that the detected intensity V4 is not more than 1.7% of the maximum value V3 of the detected intensity of gallium atoms in the second semiconductor layer 20.

The distance between the second position (concentration definition position P0) and the first position IF along the Z-axis direction (stacking direction from the second semiconductor layer 20 toward the metal layer 80), is for example, 40 nm.

At the first position IF, the detected intensity of the complex composed of gallium atoms and nitrogen atoms detected by the SIMS analysis (secondary ion mass spectrometry analysis) is 1/100 times of the maximum value of the detected intensity of the complex composed of gallium atoms and nitrogen atoms in the second semiconductor layer 20.

The maximum value V3 of the Ga concentration in the second semiconductor layer 20 is, for example, the detected intensity of Ga atoms at a position of 100 nm from the first position IF of the metal layer 80 and the second semiconductor layer 20 along the Z-axis direction.

If in the SIMS analysis of the region including the metal layer 80 and the second semiconductor layer 20, the analysis of the sample to which annealing is not performed (for example, sample SPA) is possible, the following definition may be used as well.

The first definition is as follows.

In the sample SPA illustrated in FIG. 10, a position where the detected intensity of Ga atoms in the second semiconductor layer 20 is constant is taken as a standard position ps. In this example, the detected intensity Int (Ga) of Ga atoms at the position ps is about 1×10⁶.

A first interface position p01 is set in the region including the metal layer 80 and the second semiconductor layer 20. The first interface position p01 is a position in the depth Zd direction. At the first interface position p01, the detected intensity Int (Ga) of Ga atom is 1/e times of the detected intensity Int of Ga atoms at the standard position ps. “e” is a base of natural logarithm.

Thus, from the sample SPA, the first interface position p01 is determined as the standard position along the thickness Zd direction in the SIMS analysis. In this example, a position of the depth Zd of about 170 nm is the first interface position p01.

A region where the Ga concentration in the metal layer 80 decreases and a region where the Ga concentration in the metal layer 80 increases along the Z-axis direction from the second semiconductor layer 20 toward the metal layer 80 are observed in each sample. In SIMS analysis, generally, the detected value is not always correct in a region near to a surface (region with a depth Zd not more than 10 nm). In order to exclude the value in this region, the region where the Ga concentration in the metal layer 80 decreases along the Z-axis direction from the second semiconductor layer 20 toward the metal layer 80 in the second semiconductor layer 20 is conveniently used as a region for defining the Ga concentration.

In each sample, a position where the detected intensity of Ga atoms in the metal layer 80 is the minimum is taken as the minimum position. The detected intensity of Ga atoms in the metal layer 80 is maximum at the first interface position p01. A position in the intermediate between the above minimum position and the first interface position p01 in the Z-axis direction is taken as an intermediate position. The detected intensity of Ga atoms at the intermediate position (first detected intensity) can be used as the detected intensity of Ga atoms in the metal layer 80 in each sample. A ratio of the detected intensity of Ga atoms at the intermediate position to the detected intensity Int (Ga) (about 1×10⁶) at the standard position ps is taken as a first ratio R1.

For example, for the sample N5O3, the first detected intensity is about 2×10², and the first ratio is about 0.1%.

For example, for the sample N6O3, the first detected intensity is about 3×10⁴, and the first ratio is about 3%.

For example, for the sample N7O3, the first detected intensity is about 1.4×10⁴, and the first ratio is about 1.2%.

For example, for the sample N8O3, the first detected intensity is about 7×10³, and the first ratio is about 0.7%.

For example, for the sample N8OX, the first detected intensity is about 1×10³, and the first ratio is about 0.1%.

In the case of using this definition, the first ratio R1 is preferable to be larger than 0.1% and smaller than 3%. The first ratio R1 is preferable to be not less than 0.7%. The first ratio R1 is preferable to be not more than 1.2%.

The second definition is as follows.

In the sample SPA illustrated in FIG. 10, a second interface position p02 is set in a region including the metal layer 80 and the second semiconductor layer 20. The second interface position p02 is a position in the Z-axis direction. At the second interface position p02, the detected intensity Int (Ga) of Ga atoms is 1/100,000 times of the detected intensity Int (Ga) of Ga atoms at the standard position ps.

Also in this case, the standard position ps is a position with a constant detected intensity of Ga atoms in the second semiconductor layer 20, and the detected intensity Int (Ga) of Ga atoms at the standard position ps is about 1×10⁶. Similar to the first definition, the Ga concentration in the metal layer 80 is defined.

In other words, a position where the detected intensity of Ga atoms in the metal layer 80 is minimum is taken as the minimum position. The detected intensity of Ga atoms in the metal layer 80 is maximum at the second interface position p02. An average value (second detected intensity) of the detected intensity of Ga atoms between the above minimum position and the second interface position p02 is used as the detected intensity of Ga atoms in the metal layer 80 of each sample. A ration of the average of the detected intensity of Ga atoms to the detected intensity Int (Ga) (about 1×10⁶) of Ga atoms at the standard position ps is taken as a second ratio R2.

The second detected intensity has almost the same value as the first detected intensity in each sample. In the case of using the second definition, the second ratio R2 is preferable to be larger than 0.1% and smaller than 3%. The second ratio R2 is preferable to be not less than 0.7%. The second ratio R2 is preferable to be not more than 1.2%.

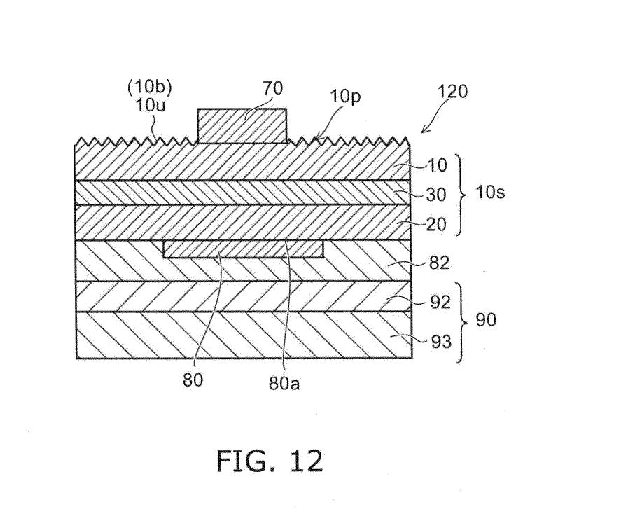

FIG. 12 is a schematic cross sectional diagram showing a configuration of another semiconductor light emitting device of the first embodiment.

As shown in FIG. 12, another semiconductor light emitting device 120 of the embodiment further includes, in addition to a semiconductor stacked unit 10s and a metal layer 80, an opposing side electrode 70, a supporting substrate unit 90, and an adhered metal layer 82. In the semiconductor light emitting device 120, the metal layer 80 is electrically connected with a second semiconductor layer 20, and the opposing side electrode 70 is electrically connected with a first semiconductor layer 10.

The supporting substrate unit 90 includes a conductive substrate 93, and a conductive layer 92 provided on the conductive substrate 93. For example, silicon substrate may be used as the conductive substrate 93. The adhered metal layer 82 is provided between the conductive layer 92 and the opposing side electrode 70, and electrically connects the conductive layer 92 and the opposing side electrode 70. The adhered metal layer 82 and the conductive layer 92 are in contact with one another. A current flows in a light emitting layer 30 by applying a voltage between the conductive substrate 93 and the opposing side electrode 70, and light is thereby discharged.

In this example, a rugged pattern 10p is formed on a surface 10u (second main surface 10b) on an opposite side of the light emitting layer 30 in the first semiconductor layer 10. Height of the rugged pattern 10p is larger than the dominant wavelength of the light discharged from the light emitting layer 30.

In this case also, the metal layer 80 is oriented toward <111>. For example, the height of the peak belonging to the (100) plane is at or less than 3% of the height of the peak belonging to the (111) plane of Ag.

Further, the average area of the plurality of grains 301 of the metal layer 80 is 5 μm² or more and 100 μm² or less. Further, the contact resistance Rc between the metal layer 80 and the semiconductor stacked unit 10s is 1.5×10⁻⁴ Ωcm² or more and 1.5×10⁻³ Ωcm² or less.

Accordingly, in the semiconductor light emitting device 120 also, a semiconductor light emitting device having an electrode with low contact resistance and high reflectivity can be provided.

Hereinbelow, an example of a method for manufacturing the semiconductor light emitting device 120 will be described.

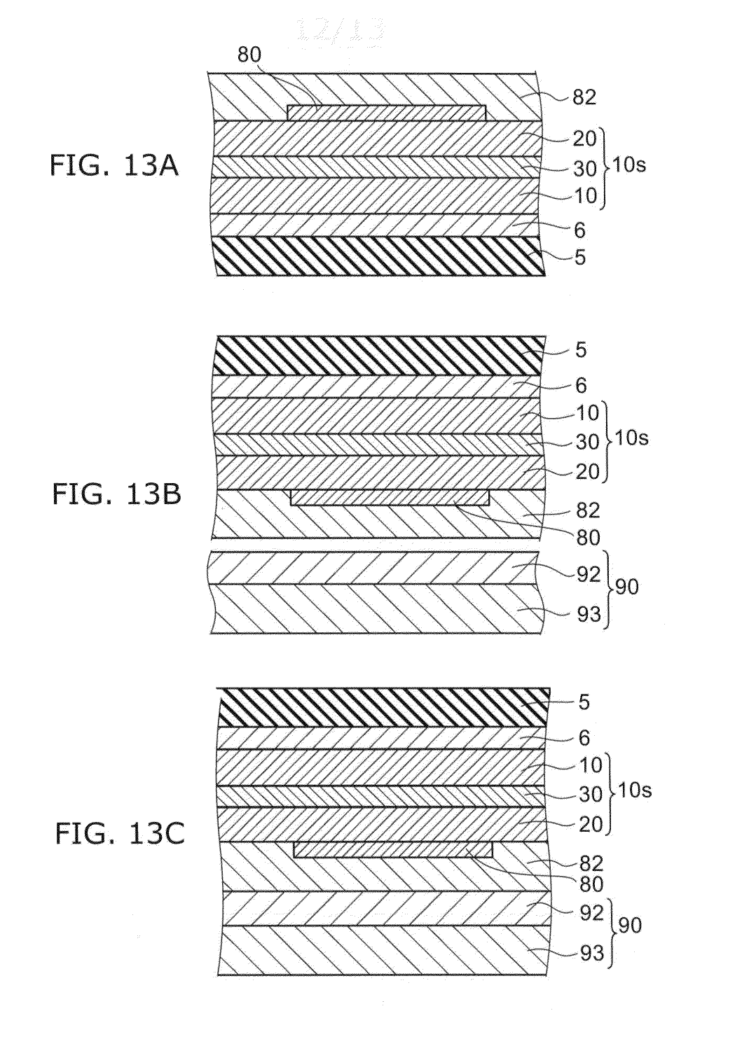

FIG. 13A to FIG. 13C, FIG. 14A, and FIG. 14B are schematic cross sectional diagrams in a processing order showing a method for manufacturing another semiconductor light emitting device of the first embodiment.

In the manufacturing method below, for example, a metal organic chemical vapor deposition (MOCVD) is used for a crystal growth of the semiconductor layer. Other than this, a molecular beam epitaxy (MBE) may be used for the crystal growth.

As shown in FIG. 13A, the buffer layer 6 is formed on the main surface of the substrate 5 such as the c-plane sapphire and the like. Various materials such as GaN, SiC, Si, and GaAs and the like may be used as the substrate 5. For example, Alₓ₀Ga₁₋ₓ₀N (0≦x0≦1) layer is used as the buffer layer 6. A crystal of the first semiconductor layer 10 is grown on the buffer layer 6. For example, n-type GaN layer and the like is used as the first semiconductor layer 10. A crystal of the light emitting layer 30 is grown on the first semiconductor layer 10. Various configurations as described in connection to FIG. 2A to FIG. 2C are adapted as the light emitting layer 30. A crystal of the second semiconductor layer 20 is grown on the light emitting layer 30. For example, p-type GaN layer and the like is used as the second semiconductor layer 20.

Ag film that is to be the metal layer 80 is formed on the second semiconductor layer 20. Thereafter, annealing in the nitrogen atmosphere at 800° C. is performed for 1 min, and after that, annealing in the oxygen atmosphere at 300° C. is performed for 1 min. Due to this, the metal layer 80 is formed. The adhered metal layer 82 is formed by staking the Ti film, the Pt film and the Au film in this order so as to cover the metal layer 80.

As shown in FIG. 13B, the supporting substrate unit 90 including the conductive substrate 93 (for example, silicon substrate), and the conductive layer 92 provided on the main surface of the conductive substrate 93 is prepared. The conductive layer 92 and the adhered metal layer 82 are caused to oppose one another. A layer containing Au and Sn is used as the conductive layer 92. Pressure is applied over a certain period of time in a state of having the conductive layer 92 and the adhered metal layer 82 in contact, for example, under a high temperature of 250° C. or more.

Due to this, as shown in FIG. 13C, the adhered metal layer 82 and the conductive layer 92 are adhered to one another.

Further, ultraviolet laser (for example, laser having KrF wavelength of 248 nm) is irradiated in pulses from an opposite side of the first semiconductor layer 10 of the substrate 5.

Due to this, as shown in FIG. 14A, the semiconductor stacked unit 10s is exfoliated from the substrate 5. Accordingly, by removing the substrate 5 used in forming the semiconductor stacked unit 10s, heat diffusing property can be improved, and high light emitting efficiency can be obtained in the semiconductor light emitting device 120.

Thereafter, the semiconductor stacked unit 10s is processed into a certain shape. That is, a plurality of semiconductor stacked units 10s is formed on the substrate 5, and the plurality of semiconductor stacked units 10s is separated individually. Note that, at this occasion, the adhered metal layer 82 is not patterned between the separated plurality of semiconductor stacked units 10s, and at between semiconductor crystal films separated for each of the semiconductor stacked units 10s, the adhered metal layer 82 is in a state of being exposed. Further, the patterned semiconductor crystal films for example have tapered mesa shapes.

Next, as a protection film, for example, a SiO₂ film is formed. Note that, by having the mesa shape, covering property of the protection film is improved. The surface of the first semiconductor layer 10 is exposed by removing a part of the protection film.

As shown in FIG. 14B, the opposing side electrode 70 is formed on the surface of the first semiconductor layer 10. Thereafter, the first semiconductor layer 10 is wet etched. In this etching, for example, potassium hydroxide with a concentration of 1 mol/l and a temperature of 70° C. is used, and etching for 15 minutes is performed. Due to this, the surface of the first semiconductor layer 10 is roughened. That is, the rugged pattern 10p is formed on the surface of the first semiconductor layer 10.

Note that, for the opposing side electrode 70, for example, an alkali tolerant material is used. For the opposing side electrode 70, for example, a material of at least one of Pt, Au, Ni, and Ti is used. By using this material, a size (difference of elevation) of the rugged pattern 10p formed by the alkali etching can be made large.

By the foregoing processes, the semiconductor light emitting device 120 shown in FIG. 12 can be manufactured.

### Second Embodiment

The embodiment relates to a method for manufacturing a semiconductor light emitting device.

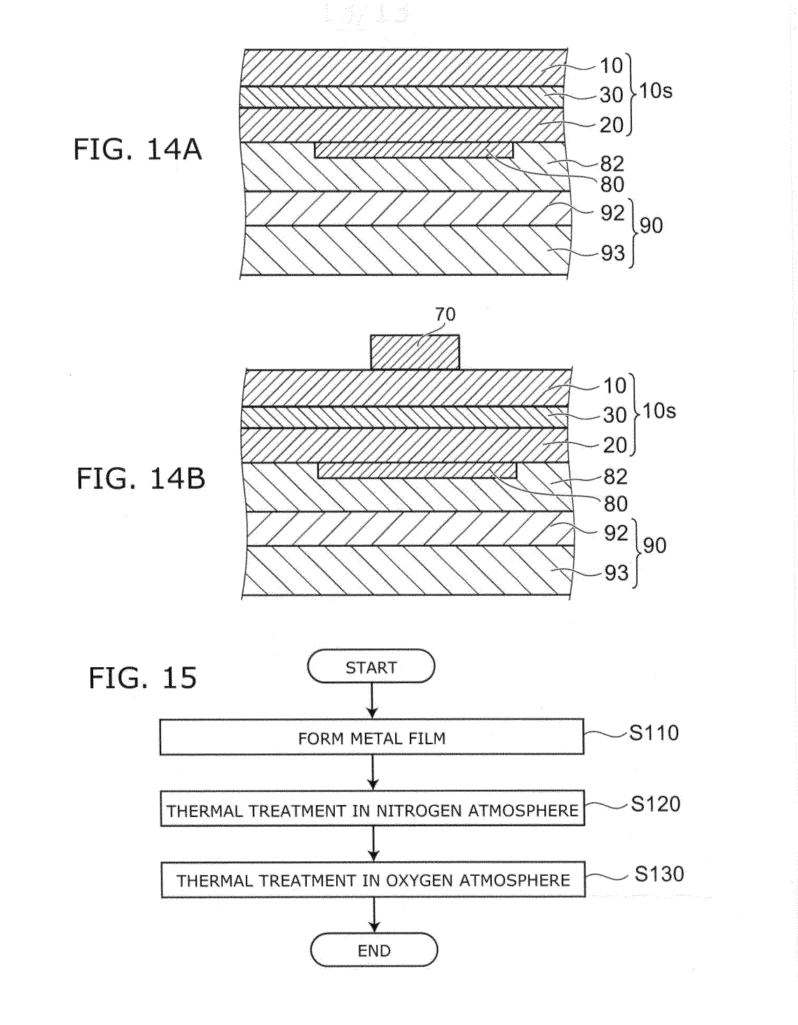

FIG. 15 is a diagram of a flowchart showing the method for manufacturing a semiconductor light emitting device of the second embodiment.

As shown in FIG. 15, a metal film (silver film) containing Ag is formed on a semiconductor stacked unit 10s including a light emitting layer 30 and containing nitride semiconductor (step S110). A first thermal processing of thermally treating the metal film in an atmosphere including nitrogen is performed (step S120). Further, after the first thermal processing, a second thermal processing of thermally treating the metal film in an atmosphere including oxygen is performed (step S130). A temperature of the thermal treatment in the first thermal processing is higher than a temperature of the thermal treatment in the second thermal processing. Due to this, a semiconductor light emitting device having an electrode with low contact resistance and high reflectivity can be manufactured.

The temperature of the thermal treatment in the first thermal processing is 700° C. or more and 800° C. or less. The temperature of the thermal treatment in the second thermal processing is 200° C. or more and 400° C. or less. Due to this, as described in relation to FIG. 5 and FIG. 6, an electrode (metal layer 80) with low contact resistance and high reflectivity can be obtained. Time of the thermal treatment in the first thermal processing is for example 1 min or more and 10 min or less. When the time is less than 1 min, the crystal growth is insufficient, so the suppression of migration in the second thermal processing becomes insufficient. When the time exceeds 10 min, damages to a semiconductor stacked unit may be caused. Time of the thermal treatment in the second thermal processing is for example 30 sec (seconds) or more and 1 min or less. When the time is less than 30 sec, the reduction of the contact resistance is insufficient. When the time exceeds 1 min, the migration is enhanced, and the reflectivity is reduced.

In the manufacturing method according to the embodiment, after the second thermal process, a height of peak belonging to a (100) plane of Ag is, for example, not more than 3% of a height of peak belonging to a (111) plane of Ag in an X-ray diffraction analysis.

In the SIMS analysis after the second thermal process, the detected intensity V2 of the complex composed of gallium atom and nitrogen atom at the first position IF is 1/100 times of the maximum value V1 of the detected intensity of the complex composed of gallium atom and nitrogen atom in the semiconductor layer. The first position IF is located in a region including the semiconductor layer (in this example, second semiconductor layer) and the silver film. The first position IF is a position along the stacking direction from the semiconductor layer toward the silver film.

In the SIMS analysis after the second thermal process, the detected intensity V4 of gallium atoms at the second position (concentration definition position P0) at is higher than 0.4% and lower than 3.8% of the maximum value V3 of the detected intensity of gallium atoms in the semiconductor layer. The second position (concentration definition position P0) is a position at a distance of 40 nm from the first position IF in the silver film. This allows the low contact resistance Rc to be achieved. The detected intensity V4 is desirable to be not less than 1.4% of the maximum value V3. The detected intensity V4 is desirable to be not more than 1.7% of the maximum value V3.

According to the embodiment, a semiconductor light emitting device having an electrode with low contact resistance and high reflectivity is provided.

Note that, in the specification, “nitride semiconductor” includes semiconductors having any composition that is derived by changing composition ratios x, y, and z within respective ranges in a chemical formula of BₓIn_{y}Al_{z}Ga_{1-x-y-z}N (0≦x≦1, 0≦y≦1, 0≦z≦1, x+y+z≦1). Moreover, in the above chemical formula, those further including group V compounds other than N (nitrogen), those further including various elements added for controlling various physical properties such as a conductivity type, and those further including various elements unintentionally included are also included in the “nitride semiconductor”.

As described above, embodiments of the invention have been described with reference to specific examples. However, the embodiments of the invention are not limited to these specific examples. For example, specific configurations of the respective components such as the semiconductor layer, the n-type semiconductor layer, the p-type semiconductor layer, the light emitting layer, a transparent electrode layer, the electrode and the like are included in the scope of the invention so long as the invention can similarly be carried out and similar effects can be obtained by a person skilled in the art by appropriately selecting those from known ranges.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a semiconductor stacked unit including
a light emitting layer including a nitride semiconductor, and
a semiconductor layer provided on the light emitting layer, the semiconductor layer containing gallium; and
a silver layer being in contact with the semiconductor layer,
a height of a peak belonging to a (100) plane of silver of the silver layer being not more than 3% of a height of a peak belonging to a (111) plane of silver of the silver in an X-ray analysis,
a detected intensity of a complex of gallium atoms and nitrogen atoms at a first position being 1/100 of a maximum value of a detected intensity of the complex in the semiconductor layer in a secondary ion mass analysis, the first position being in a region including the semiconductor layer and the silver layer and along a stacking direction from the semiconductor layer toward the silver layer,
a detected intensity of gallium atoms at a second position being higher than 0.4% and lower than 3.8% of a maximum value of a detected intensity of gallium atoms in the semiconductor layer in the secondary ion mass analysis, the second position being in the silver layer, and a distance between the second position and the first position being 40 nm.

2. The device according to claim 1, wherein the detected intensity of Gallium atoms at the second position is not less than 1.4% and not more than 1.7% of the maximum value of gallium atoms in the semiconductor layer.

3. The device according to claim 1, wherein the silver layer includes a plurality of grains, and an average area of the grains in a plane perpendicular to the stacking direction is not less than 5 μm² and not more than 100 μm².

4. The device according to claim 1, wherein a specific contact resistivity between the silver layer and the semiconductor stacked unit is 1.5×10⁻³ Ωcm² or less.

5. The device according to claim 1, wherein a specific contact resistivity between the silver layer and the semiconductor stacked unit is not less than 1.5×10⁻⁴ Ωcm².

6. The device according to claim 1, wherein a portion within the silver layer being in contact with the semiconductor stacked unit is an Ag film.

7. The device according to claim 1, wherein the semiconductor stacked unit further includes an n-type first semiconductor layer and a p-type second semiconductor layer, and
the light emitting layer is provided between the first semiconductor layer and the second semiconductor layer.

8. The device according to claim 7, wherein the first semiconductor layer and the second semiconductor layer include a nitride semiconductor.

9. The device according to claim 7, wherein the silver layer is electrically connected with the second semiconductor layer.

10. The device according to claim 9, further comprising an opposing side electrode electrically connected with the first semiconductor layer.

11. The device according to claim 9, further comprising a substrate having a first surface,
the first semiconductor layer being provided between the first surface and the light emitting layer, and
the first surface is a (0001) plane.

12. The device according to claim 7, wherein the silver layer is electrically connected with the first semiconductor layer.

13. The device according to claim 12, further comprising an opposing side electrode that is electrically connected with the second semiconductor layer.

14. The device according to claim 12, wherein the first semiconductor layer has a rugged pattern provided on a surface on an opposite side from the light emitting layer of the first semiconductor layer, and a height of the rugged pattern is higher than a dominant wavelength of a light emitted from the light emitting layer.

15. The device according to claim 13, wherein the opposing side electrode includes at least one of Pt, Au, Ni, and Ti.

16. The device according to claim 1, wherein a wavelength of an emitted light emitted from the light emitting layer is not less than 360 nm and not more than 580 nm.

17. A method for manufacturing a semiconductor light emitting device, the method comprising:
forming a sliver film on a semiconductor layer provided on a light emitting layer of a nitride semiconductor, the semiconductor layer containing gallium;
performing a first thermal process including a thermal treatment of the silver film in an atmosphere containing nitrogen at a first temperature; and
performing a second thermal process including a thermal treatment of the silver film in an atmosphere containing oxygen at a second temperature after the first thermal process,
the first temperature being higher than the second temperature,
after the second thermal process, a height of a peak belonging to a (100) plane of silver of the silver film being not more than 3% of a height of a peak belonging to a (111) plane of silver of the silver film in an X-ray analysis,
after the second thermal process, a detected intensity of a complex of gallium atoms and nitrogen atoms at a first position being 1/100 of a maximum value of a detected intensity of the complex in the semiconductor layer in a secondary ion mass analysis, the first position being in a region including the semiconductor layer and the silver film and along a stacking direction from the semiconductor layer toward the silver film,
after the second thermal process, a detected intensity of gallium atoms at a second position being higher than 0.4% and lower than 3.8% of a maximum value of a detected intensity of gallium atoms in the semiconductor layer in the secondary ion mass analysis, the second position being in the silver film, and a distance between the second position and the first position being 40 nm.

18. The method according to claim 17, wherein the detected intensity of Gallium atoms at the second position is not less than 1.4% and not more than 1.7% of the maximum value of gallium atoms in the semiconductor layer.

19. The method according to claim 17, wherein the first temperature is not less than 700° C. and not more than 800° C., and
the second temperature is not less than 200° C. and not more than 400° C.

20. The method according to claim 17, wherein a time of the thermal treatment in the first thermal process is not less than 1 minute and not more than 10 minutes, and
a time of the thermal treatment in the second thermal process is not less than 30 seconds and not more than 1 minute.
